(19) United States
(12) Patent Application Publication
(10) Pub. No.: US 2025/0014972 A1
(43) Pub. Date: Jan. 9, 2025

(54) PACKAGE WITH CLIP DIRECTLY CONNECTED TO OBLONG ELECTRIC CONNECTION ELEMENT EXTENDING ALONG MOUNTING BASE

(71) Applicant: Infineon Technologies AG, Neubiberg (DE)

(72) Inventors: Tomasz NAEVE, Finkenstein (AT); Kapil KELKAR, Torrance, CA (US); Homayoun MORAGHEBI, El Segundo, CA (US)

(73) Assignee: Infineon Technologies AG, Neubiberg (DE)

(21) Appl. No.: 18/747,095

(22) Filed: Jun. 18, 2024

(30) Foreign Application Priority Data
Jul. 3, 2023 (DE) 10 2023 206 287.9

(51) Int. Cl. H01L 23/495; H01L 23/00; H01L 25/065

(52) U.S. Cl. CPC H01L 23/49575; H01L 23/4951; H01L 23/49568; H01L 24/05; H01L 24/37; H01L 25/0652; H01L 2224/05005; H01L 2224/05022; H01L 2224/37005; H01L 2224/3702; H01L 2924/01013; H01L 2924/01029; H01L 2924/1203; H01L 2924/13091

(57) ABSTRACT

A package and electronic device are disclosed. In one example, the electronic device comprises a mounting base, an oblong electric connection element, and a package mounted on the mounting base and comprising a carrier, electronic components mounted on the carrier, and an encapsulant at least partially encapsulating the carrier and the electronic components. A clip is connected to upper main surfaces of the electronic components. The encapsulant partially encapsulates the clip so that an exposed surface of the clip is directly electrically connected with the oblong electric connection element extending along the mounting base.

### CROSS-REFERENCE TO RELATED APPLICATION

This Utility Patent Application claims priority to German Patent Application No. 10 2023 206 287.9 filed Jul. 3, 2023, which is incorporated herein by reference.

### BACKGROUND

### Technical Field

Various embodiments relate generally to an electronic device, and a method of manufacturing an electronic device.

### Description of the Related Art

Packages may be denoted as encapsulated electronic components with electrical connections extending out of the encapsulant and being mounted to an electronic periphery, for instance on a printed circuit board.

Packaging cost is an important driver for the industry. Related with this are performance, dimensions and reliability. The different packaging solutions are manifold and have to address the needs of the application. In particular, overheating packages during operation may reduce reliability and performance of the package.

### SUMMARY

There may be a need to provide an electronic device with high electric performance and thermal reliability.

According to an exemplary embodiment, an electronic device is provided which comprises a mounting base, an oblong electric connection element, and a package mounted on the mounting base and comprising a carrier, electronic components mounted on the carrier, an encapsulant at least partially encapsulating the carrier and the electronic components, and a clip connected to upper main surfaces of the electronic components, wherein the oblong electric connection element is electrically connected directly on top of the clip so as to extend for conducting electricity from or to the clip along at least part of the mounting base.

According to another exemplary embodiment, a method of manufacturing an electronic device is provided, wherein the method comprises forming a package by mounting electronic components on a carrier, at least partially encapsulating the carrier and the electronic components by an encapsulant, and connecting a clip to upper main surfaces of the electronic components, mounting the package on a mounting base, and electrically connecting an oblong electric connection element directly on top of the clip so as to extend for conducting electricity from or to the clip along at least part of the mounting base.

According to an exemplary embodiment, an electronic device is composed of a mounting base and a package mounted thereon, wherein the package is connected by an oblong electric connection element. The package may comprise a carrier and electronic components mounted thereon, wherein an encapsulant encapsulates carrier and electronic components. A clip is connected to the top side of the electronic components. Advantageously, the oblong electric connection element may be electrically coupled directly (i.e. without electronic members in between) on top of the clip. This coupling can be accomplished so that the oblong electric connection element extends for conducting electricity from and/or to the clip along the and at least in a section vertically spaced with respect to the mounting base. It has been found that the described configuration of a direct connection between a top-sided package clip and an oblong electric connection element extending along the mounting base provides an excellent temperature and therefore allows to operate the electronic device at higher power level. Surprisingly, thermal reliability and power performance with the described configuration may be even better than with the use of a bulk connector on top of the clip. As a result, a package-based electronic device with excellent electric and thermal reliability as well as outstanding performance may be obtained, even usable in high current power applications. In a scenario in which a moderate cooling is sufficient, a separate heat sink may even become dispensable.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a three-dimensional exploded view of constituents of a package of an electronic device according to an exemplary embodiment.

FIG. 2 illustrates a cross-sectional view of an electronic device according to an exemplary embodiment.

FIG. 3 illustrates a plan view of an electronic device according to an exemplary embodiment.

FIG. 4 illustrates a plan view of an electronic device according to another exemplary embodiment.

FIG. 5 illustrates a plan view of an electronic device according to another exemplary embodiment.

FIG. 6 illustrates a plan view of an electronic device according to another exemplary embodiment.

FIG. 7 illustrates a plan view of an electronic device according to another exemplary embodiment.

FIG. 8 illustrates a plan view of an electronic device according to another exemplary embodiment.

FIG. 9 illustrates a plan view of a cooling structure and a thermal interface material of an electronic device according to an exemplary embodiment.

FIG. 10 illustrates a plan view of an electronic device with a cooling structure and a thermal interface material according to an exemplary embodiment.

FIG. 11 illustrates a cross-sectional view of an electronic device with protection structure according to another exemplary embodiment.

FIG. 12 illustrates a plan view of an electronic device with protection structures according to another exemplary embodiment.

### DETAILED DESCRIPTION

There may be a need to provide an electronic device with high electric performance and thermal reliability.

According to an exemplary embodiment, an electronic device is provided which comprises a mounting base, an oblong electric connection element, and a package mounted on the mounting base and comprising a carrier, electronic components mounted on the carrier, an encapsulant at least partially encapsulating the carrier and the electronic components, and a clip connected to upper main surfaces of the electronic components, wherein the oblong electric connection element is electrically connected directly on top of the clip so as to extend for conducting electricity from or to the clip along at least part of the mounting base.

According to another exemplary embodiment, a method of manufacturing an electronic device is provided, wherein the method comprises forming a package by mounting electronic components on a carrier, at least partially encapsulating the carrier and the electronic components by an encapsulant, and connecting a clip to upper main surfaces of the electronic components, mounting the package on a mounting base, and electrically connecting an oblong electric connection element directly on top of the clip so as to extend for conducting electricity from or to the clip along at least part of the mounting base.

According to an exemplary embodiment, an electronic device is composed of a mounting base and a package mounted thereon, wherein the package is connected by an oblong electric connection element. The package may comprise a carrier and electronic components mounted thereon, wherein an encapsulant encapsulates carrier and electronic components. A clip is connected to the top side of the electronic components. Advantageously, the oblong electric connection element may be electrically coupled directly (i.e. without electronic members in between) on top of the clip. This coupling can be accomplished so that the oblong electric connection element extends for conducting electricity from and/or to the clip along the and at least in a section vertically spaced with respect to the mounting base. It has been found that the described configuration of a direct connection between a top-sided package clip and an oblong electric connection element extending along the mounting base provides an excellent temperature and therefore allows to operate the electronic device at higher power level. Surprisingly, thermal reliability and power performance with the described configuration may be even better than with the use of a bulk connector on top of the clip. As a result, a package-based electronic device with excellent electric and thermal reliability as well as outstanding performance may be obtained, even usable in high current power applications. In a scenario in which a moderate cooling is sufficient, a separate heat sink may even become dispensable.

### DESCRIPTION OF FURTHER EXEMPLARY EMBODIMENTS

In the following, further exemplary embodiments of the electronic device, and the method will be explained.

In the context of the present application, the term “electronic device” may particularly denote an apparatus comprising at least one package mounted on a mounting base and being electrically interconnected by at least one oblong electric connection element. Optionally, the electronic device may comprise one or more further electronic members. For example, the electronic device may be a motor control for an electric motor, may comprise an electric motor with motor control, or may be an electric car with such an electric motor or motor control.

In the context of the present application, the term “mounting base” may particularly denote a support body on which a package may be mounted. For instance, such a mounting base may be a printed circuit board (PCB), or another preferably plate-shaped electronic board.

In the context of the present application, the term “package” may particularly denote a device which may comprise electronic components mounted on a carrier, wherein said carrier may comprise or consist of a single part, multiple parts joined via encapsulation or other package components, or a subassembly of carriers. Said constituents of the package may be encapsulated at least partially by an encapsulant. It is also possible that one or more clips, as electrically conductive interconnect bodies, may be implemented in a package, for instance for electrically coupling the electronic components with the carrier and/or with an electronic periphery. Also the clip may be at least partially encapsulated.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed for example in silicon technology, gallium nitride technology, silicon carbide technology, etc.

In the context of the present application, the term “carrier” may particularly denote a support structure (which may be at least partially electrically conductive) which serves as a mechanical support for the electronic components to be mounted thereon, and which may also contribute to the electric interconnection between the electronic components and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad.

In the context of the present application, the term “encapsulant” may particularly denote a substantially electrically insulating material surrounding at least part of an electronic component and at least part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In the context of the present application, the term “clip” may particularly denote an electrically conductive plate structure for connection to electronic components, and optionally also to a carrier. More specifically, a clip may be a three-dimensionally bent plate type connection element which has two planar sections to be connected to an upper main surface of the respective electronic component. An upper main surface of the clip may be connected to a carrier.

In the context of the present application, the term “oblong electric connection element” may particularly denote an elongate or longish element which may be made at least partially of an electrically conductive material. The oblong electric connection element may have a dimension in one direction or extension being larger than the dimensions in directions or extensions perpendicular to said largest dimension. For instance, the largest dimension may be at least three times or at least five times of the dimensions in said perpendicular directions or extensions. For instance, the oblong electric connection element may extend straight, for instance when embodied as a metal strip. It is however also possible that the oblong electric connection element is curved, for example when being embodied as electric cable. The extension of the oblong electric connection element may be predominantly or completely horizontally. For example, the oblong electric connection element may extend with its largest dimension predominantly or entirely in parallel to a main surface of the mounting base, which may be plate-shaped. An oblong electric connection element, when being in a straight configuration, may have a ratio between length and maximum diameter in a plane perpendicular to the length direction of at least three, in particular at least five, for example at least ten.

In the context of the present application, the term “connecting an oblong electric connection element directly on top of the clip so as to extend for conducting electricity from or to the clip along at least part of the mounting base” may particularly denote that the oblong electric connection element may be electrically coupled with the clip without a further intermediate electronic member in between. For example, the oblong electric connection element may be connected directly with the clip by soldering, sintering, electrically conductive glue or by a direct metal-metal-connection (for instance formed by hybrid bonding). Hence, either no material at all (for example in the case of hybrid bonding) or only an electrically conductive connection medium (such as a solder structure, sinter paste or electrically conductive glue) may be arranged between clip and oblong electric connection element. The direct connection between clip and oblong electric connection element may be accomplished so that the oblong electric connection element extends completely or predominantly along an extension of the mounting base, for instance completely or predominantly horizontally, rather than vertically.

In an embodiment, the oblong electric connection element is electrically connected directly horizontally on the clip. Hence, the oblong electric connection element may extend horizontally from and along at least part of the clip, and optionally also along the mounting base, at least in a connection region between oblong electric connection element and clip. Thus, the oblong electric connection element may start to extend horizontally or at least substantially horizontally directly from the connection area with the clip onwards. This design is in contrast to a bulk connector protruding vertically from the clip. By the direct horizontal connection of the oblong connection element where extending from the clip, the thermal reliability and the power performance of the electronic device may be strongly enhanced.

In an embodiment, the oblong electric connection element is electrically connected on the clip by one of the group comprising a solder connection, a sinter connection, and a glue connection. More generally, the oblong electric connection element may be electrically connected to the clip directly and only by an electrically conductive connection structure (i.e. solder, sinter or electrically conductive glue). However, no additional electronic members may be provided between oblong electric connection element and clip so as to keep the electric paths short and the thermal dissipation efficient.

In an embodiment, the oblong electric connection element comprises a cable and/or a metal sheet (such as a metal strip):

In an embodiment, the oblong electric connection element comprises or consists of a cable. Such a cable may have an electrically conductive core surrounded by an electrically insulating cladding. Alternatively, the carrier may consist of an electrically conductive wire or filament. Such a cable may extend substantially horizontally along the mounting base or may be curved at least in a section thereof.

In an embodiment, the oblong electric connection element comprises a metal sheet, for example a metal strip. Such a metal sheet may be flat or planar. The metal sheet may extend horizontally. For example, the metal sheet may be a metal strip or a metal plate. Optionally, the metal sheet may be provided with an electrical insulation. By a metal sheet, a very high current can be transmitted in a low-ohmic fashion. The planar geometry of a metal sheet may be perfectly compatible with the direct horizontal electric connection with the planar top main surface of the clip.

In an embodiment, the electronic device comprises a cable being electrically connected with the metal sheet. The connection between cable and metal sheet may be direct (i.e. without electronic member in between) or indirect (i.e. with an additional electronic member in between, such as a bulk connector). Hence, even a cable-metal sheet connection may provide an electric coupling of the top side of the clip extending laterally or entirely along the surface of the mounting base.

In an embodiment, the electronic device comprises an electrically conductive bulk connector electrically connecting the cable with the metal sheet, for example by screwing. The bulk connector is arranged spatially apart from the package. In the context of the present application, the term “bulk connector” may particularly denote a solid (and preferably massive) electrically conductive block for electrically connecting a package with an electronic environment via an oblong connection element. In particular, the bulk connector may be a three-dimensional body having a volume larger than, in particular at least three times of, a volume of the package (i.e. a package body comprising carrier, electronic components, encapsulant and clip). Such a bulk connector may be configured for high current applications, as those which may occur in power semiconductor technology. In particular, a bulk connector may consist only of electrically conductive, in particular metallic, material.

In an embodiment, the electrically conductive bulk connector is mounted on and extends vertically from the mounting base. Hence, the electrically conductive bulk connector may be arranged spatially apart from the package. Both the package and the electrically conductive bulk connector may be mounted on the same preferably flat mounting base and may extend from the same vertical base level.

In an embodiment, the electrically conductive bulk connector is a metal block, in particular a cylindrical metal block. The electrically conductive bulk connector may comprise a fastening provision for fastening a sheet and or a cable thereon and/or therein. For instance, such a fastening task may be executed using a fastening element, operating with the electrically conductive bulk connector for fastening. For example such a fastening element may for instance be a screw, bolt or nail.

In an embodiment, the cable is directly electrically connected with the metal sheet, for example by screwing. Thus, the mentioned connection may be established by screwing a screw in a recess of the electrically conductive bulk connector with internal thread.

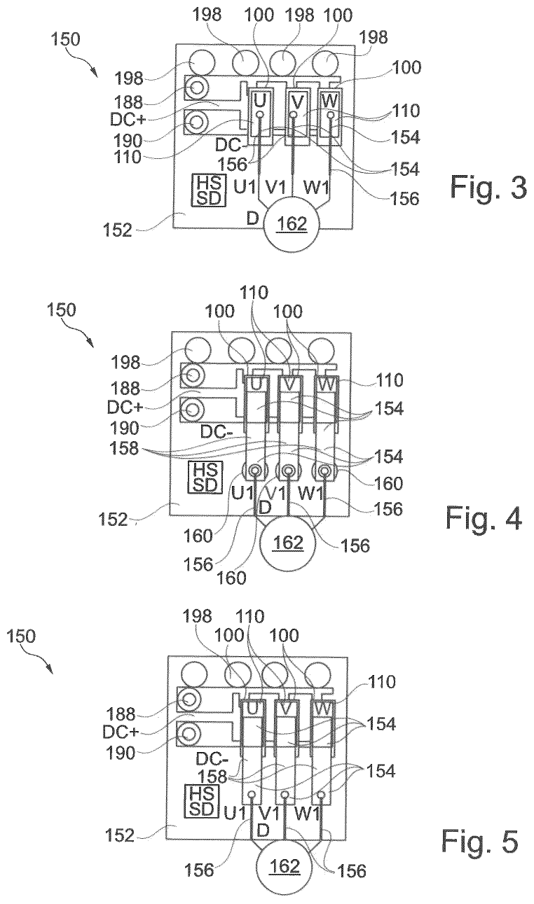

In an embodiment, the electronic device comprises at least one further package having the above-mentioned features, for example two further or five further packages, mounted on the mounting base, and at least one further oblong electric connection element being electrically connected directly on top of at least one further clip of the at least one further package so as to extend for conducting electricity from or to the at least one further clip along at least part of the mounting base. Such embodiments are shown in FIG. 3 to FIG. 8. Hence, in particular three packages or six packages may be mounted on the same mounting base. All of said packages may be mounted on the same mounting base with a direct connection between respective clip and respective oblong electric connection element. Three such packages on a mounting base may form three half bridges each corresponding to a respective phase of a three-phase motor. Six such packages on a mounting base may form six half bridges enabling paralleling of half bridges for a three-phase motor. The described configuration allows to execute a motor control with excellent cooling performance therefore enabling motor operation at a high power level.

In an embodiment, the electronic device comprises an electric motor electrically coupled with the package, for example with the oblong electric connection element(s). For instance, the package connected as described above may be coupled to an electric motor in a low ohmic way and without the danger of hot spots. Such an electric motor may be implemented in an electric car, which may be an example for an electronic device according to an exemplary embodiment.

In an embodiment, the encapsulant only partially encapsulates the clip so that an exposed surface of the clip is directly electrically connected with the oblong electric connection element. Hence, the clip may be partially encapsulated and partially exposed. The exposed portion of the upper main surface of the clip may be partially used for directly connecting the oblong electric connection element, and partially for cooling. Thus, the exposed portion of the clip which is not directly connected to the oblong electric connection element may be used for efficiently dissipating heat generated by the electronic components during operation of the electronic device. In embodiments with moderate power requirements, such a configuration may be even appropriate for sufficient cooling without the need of an additional cooling structure or heat sink.

In an embodiment, the electronic device comprises a cooling structure, which may also be denoted as heat sink. In particular, such a cooling structure may comprise a base body with a plurality of cooling fins extending therefrom. However, other embodiments are possible, for instance a liquid cooling structure using a liquid coolant such as water for cooling. For example, the cooling structure may be arranged directly on the oblong electric connection element. It is also possible that the cooling structure is arranged at least partially directly on the exposed surface of the clip. These measures may lead to a highly efficient cooling.

In an embodiment, the electronic device comprises an electrically insulating thermal interface material (TIM) between, on the one hand, the cooling structure and, on the other hand, the oblong electric connection element and/or the clip. The cooling structure or heat sink may be a heat dissipation body, which may be made of a highly thermally conductive material such as copper or aluminum which may be attached via a thermal interface material (TIM) to the exposed surface of the clip and/or of the oblong electric connection element. The thermal interface material may be electrically insulating and thermally conductive so as to promote electric protection and thermal coupling.

In an embodiment, the electronic device comprises a protection structure clamping the package and the oblong electric connection element together for protecting the oblong electric connection element from tearing off. When an oblong electric connection element (which may be a tiny structure, such as a cable) is directly connected (for instance by soldering) to an exposed metal surface of a clip, there may be the risk of an undesired tear off of the oblong electric connection element, which may cause damage and loss of the electric functionality of the electronic device. In order to reliably prevent this, a protection structure may clamp the package and the oblong electric connection element together so that the risk of an undesired teat off can be reduced or fully eliminated. Advantageously, the protection structure may have a connection plate for pressing oblong electric connection element and package together and may have legs connected with the connection plate for connection of the protection structure to the mounting base.

In an embodiment, the method comprises electrically connecting the oblong electric connection element so as to extend directly horizontally from the clip. According to such a preferred embodiment, the oblong electric connection element may extend purely horizontally and parallel to the mounting base at least in its connected end section extending from the clip. This may result in a compact design in a vertical direction and in short electric connection paths leading, in turn, to low electric losses. In a preferred embodiment, the oblong electric connection element extends predominantly or entirely horizontally and predominantly or entirely parallel to the mounting base along its entire extension.

In an embodiment, the method comprises electrically connecting the oblong electric connection element on the clip by one of the group comprising soldering, sintering, and gluing. For example, soldering may be accomplished by a solder structure such as a solder bump or a diffusion solder thin film on clip and/or on oblong electric connection element. Sintering may be carried out using a sinter paste applied between clip and oblong electric connection element. An electrically conductive glue, for example comprising electrically conductive particles in an adhesive matrix, may be provided between clip and oblong electric connection element for establishing an electrically conductive glue connection. It is however also possible that the clip and the oblong electric connection element are connected with each other by a direct metal-metal-bond, for instance by hybrid bonding (for example as a copper-copper interface).

In an embodiment, the electronic components are semiconductor dies, in particular identical semiconductor dies. Preferably, both electronic components may be transistor chips. In an embodiment, each of the semiconductor dies comprises an integrated transistor, in particular a field effect transistor. More specifically, each semiconductor die may comprise a metal oxide semiconductor field effect transistor (MOSFET).

In an embodiment, the electronic components are configured and connected to provide a half-bridge function. In the context of the present application, the term “half-bridge” may particularly denote a circuit composed of an upper transistor switch (“high-side”) and a lower transistor switch (“low-side”). For instance, the transistors may be MOSFETs, i.e. metal oxide semiconductor field effect transistors. The transistors may be connected in a cascode arrangement. The two transistor switches may be turned on and off complementary to each other (in particular with a non-overlapping dead-time) by applying corresponding voltage waveforms at each of the control (in particular gate) terminals. A desired result may be a square-wave voltage at a mid-point that switches between a first electric potential (such as a DC bus voltage) and a second electric potential (such as ground). The two transistors may be interconnected with a mutual connection of their connection terminals (in particular a source terminal and a drain terminal) so that a two transistor based switch with implemented diode characteristic may be obtained. The mentioned half-bridge configuration may be used as such or alone, or may be combined with one or more further half-bridges (or other electric circuits) to realize a more complex electric function. For instance, two such half-bridges may form a full bridge. Also inverters may be composed on the basis of half-bridges.

In an embodiment, the carrier comprises a leadframe or a thermally conductive and electrically insulating sheet covered on both opposing main surfaces with an electrically conductive layer. For instance, such a carrier may be a leadframe-type structure (for instance made of copper). In another embodiment, the carrier (rather than being embodied as metallic plate sections of a leadframe, as described above) comprises a stack composed of a central electrically insulating and thermally conductive layer (such as a ceramic layer) covered on both opposing main surfaces by a respective electrically conductive layer (such as a copper layer or an aluminium layer, wherein the respective electrically conductive layer may be a continuous or a patterned layer). In particular, the carrier may be embodied as a Direct Copper Bonding (DCB) substrate, a Direct Aluminium Bonding (DAB) substrate, an Active Metal Brazed (AMB) substrate, or an Insulated Metal Substrate (IMS).

In an embodiment, a respective electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, a respective electronic component experiences a vertical current flow. The package architecture according to exemplary embodiments is particularly appropriate for high power applications in which a vertical current flow is desired, i.e. a current flow in a direction perpendicular to the two opposing main surfaces of the electronic component, one of which being used for mounting the electronic component on the carrier.

As substrate or wafer forming the basis of the electronic components, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For the encapsulant, a mold compound may be used. Such a mold compound may be provided with filler particles, for instance by enhancing thermal conductivity. It is possible that the encapsulant is a plastic-like material or a ceramic material which may be subsidized by encapsulant additives such as filler particles, additional resins or others may be used.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

According to an exemplary embodiment, an electronic device (for instance embodied as a motor control device) is provided which comprises a mounting base (such as a PCB) on a bottom side. A package can be assembled to the mounting base, for instance can be configured as a surface mounted device. The package can comprise an at least partially electrically conductive carrier (such as a chip carrier, for instance a leadframe structure) on which two or more electronic components (preferably field effect transistor semiconductor chips) are mounted. An encapsulant (for example a mold compound) encapsulates the carrier and the electronic components partially or entirely for electrically and mechanically protecting the electronic components. A clip, which may be a structured and/or bent metal plate or which may comprise two or more such structures, may be connected to the top side of the electronic components so as to be at least partially exposed beyond the encapsulant. Advantageously, an oblong electric connection element (such as a cable, a metal strip, etc.) is electrically connected (for instance soldered) directly on top of the clip. The oblong electric connection element, which may carry an electric current, can thus be arranged to extend along the mounting base or part thereof. It has turned out that such a configuration has outstanding properties in terms of thermal performance and is therefore capable of being operated with very high electric power. Alternatively, a corresponding electronic device may be operated with the same power but with reduced cooling effort. Combinations of both approaches are possible as well.

More specifically, the package may be configured as a surface mounted device (SMD) half bridge (resulting from a corresponding connection of the two electronic components being configured as transistor semiconductor chips). Such a package may be equipped with solderable top side clip for direct phase node cable connection. Said direct connection may be established between an exposed clip on a top side of the package and the cable or other kind of oblong electric connection element. An extension of said oblong electric connection element may be more horizontal than vertical, preferably predominantly or entirely horizontally.

Preferably, the package may be configured with electronic components forming an integrated half bridge with vertical current flow. For instance, a corresponding component may be a semiconductor chip having a drain terminal on one main surface and a source terminal and a gate terminal on the opposing other main surface. Electronic devices according to exemplary embodiments may be configured in accordance with low power drives applications. Exemplary embodiments may increase system efficiency, for example for motor inverters. Moreover, an electronic device according to an exemplary embodiment may increase power density. In particular, a package and phase node connection in an electronic device may allow to manage a vertical current flow in the package with a significant increase in system output power, for instance an increase by up to 30% compared with conventional approaches. Consequently, a heat sink may be omitted in certain embodiments for reducing the manufacturing effort and for reducing the dimensions of the electronic device. In particular, a higher output power may lead to an increased power density. By this increase, efficiency and improvement of the thermal reliability as well as a smaller mounting base (for example PCB) may become possible, which may further reduce the space consumption and the manufacturing effort of the electronic device. Lower losses may lead to a lower MOSFET operating temperature during operation of the electronic device. Lower power losses may also lead to a longer battery lifetime in a battery-power system, like an electric car.

According to an exemplary embodiment, a surface mounted device-type half bridge package may be provided with exposed and solderable phase node. The connection may be made by a directly soldered cable, or by a soldered metal sheet which may be attached via a surface mounted device-type bulk connector to a phase node cable. For instance, such a configuration may be used for a brushed direct current configuration for a single half bridge. It is also possible to use exemplary embodiments for a brushless single phase direct current motor (for instance in an H-bridge configuration). This may enable a better placement for direct current bus capacitors (see reference sign 198 below) with reduced loop inductance.

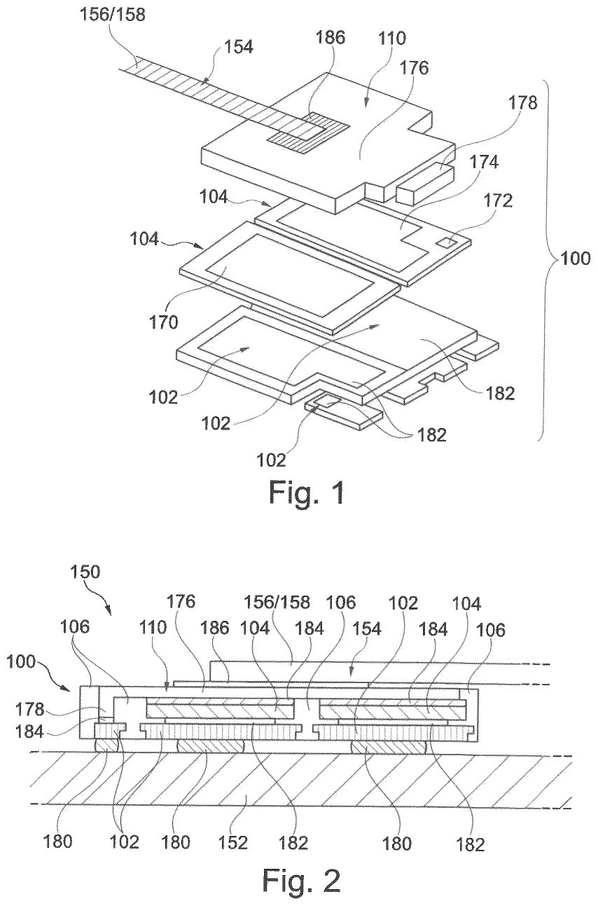

FIG. 1 illustrates a three-dimensional exploded view of constituents of a package 100 of an electronic device 150 according to an exemplary embodiment. FIG. 2 illustrates a corresponding cross-sectional view of an electronic device 150 according to an exemplary embodiment with such a package 100. For instance, the electronic device 150 shown in FIG. 2 is part of a motor control for controlling an electric motor (see reference sign 162 in FIG. 3), for instance of an electric car.

The illustrated electronic device 150 comprises a plate-shaped mounting base 152, which may for instance be a printed circuit board (PCB). The mounting base 152 is electrically and mechanically connected to package 100, which is surface mounted on the mounting base 152. A horizontally extending oblong electric connection element 154 is mounted on top of the package 100 and extends at least partially parallel to a horizontal mounting plane of the mounting base 152. For example, the oblong electric connection element 154 may comprise or consist of a cable 156 and/or a metal sheet 158.

The illustrated package 100 comprises a leadframe-type carrier 102. In other words, carrier 102 may be a structured copper plate. According to FIG. 2, solder bumps 180 (or other electrically conductive connection structures) establish a mechanical connection and an electric coupling between the carrier 102, being exposed at the bottom side of the package 100, and pads (not shown) on top of the mounting base 152.

Two thin electronic components 104 are mounted on the carrier 102 by soldering, see solder structures 182 (which may be substituted by other electrically conductive connection structures) in FIG. 1 and FIG. 2. Each electronic component 104 is embodied as a semiconductor power chip having a monolithically integrated field effect transistor. More specifically, the electronic components 104 may be MOSFET chips, one being arranged in a top sided way and the other being arranged in a bottom sided way. Each of the electronic components 104 may have one main surface with a drain terminal 170 and an opposing other main surface having a gate terminal 172 and a source terminal 174. In one of the electronic components 104, the drain terminal 170 is oriented upwardly to face away from the carrier 102, wherein the gate terminal 172 and the source terminal 174 are oriented downwardly to face the carrier 102. In the other one of the electronic components 104, the drain terminal 170 is oriented downwardly to face the carrier 102, wherein the gate terminal 172 and the source terminal 174 are oriented upwardly to face away from the carrier 102. Thus, the electronic components 104 are configured as field effect transistor chips and may have the drain terminal 170 on one main surface and the source terminal 174 and the gate terminal 172 on the other main surface. The current may flow vertically through the respective electronic component 104. The two electronic components 104 may be interconnected so as to form a half-bridge. The electronic components 104 may be embodied as two identical semiconductor dies, but may also be embodied as semiconductor dies with different properties.

Furthermore, the package 100 comprises a clip 110 connected (for instance by soldering) to upper main surfaces of the electronic components 104 and of the carrier 102, see solder structures 184 (which may be substituted by other electrically conductive connection structures). Clip 110 may be a plate-shaped (and for instance three-dimensionally bent) metallic member configured for contacting the terminals of the electronic components 104 at their upper main surfaces and configured for contacting the metallic surface of the upper side of the carrier 102. More specifically, the illustrated clip 110 has a horizontal plate section 176 being coupled with the upper main surfaces of the electronic components 104. In addition, the illustrated clip 110 has a vertical section 178 being connected (for instance being integrally connected) with the horizontal plate section 176 for establishing an electric connection with the carrier 102.

An encapsulant 106, which is here embodied as a mold compound, partially encapsulates the carrier 102 and encapsulates the electronic components 104. Moreover, the encapsulant 106 partially encapsulates the clip 110 in such a way that an upper main surface of the clip 110 remains exposed with respect to the encapsulant 106. The exposed surface of the clip 110 is directly electrically connected with the oblong electric connection element 154 by solder structure 186.

Thus, the oblong electric connection element 154 is electrically connected directly on top of the exposed clip 110 by a solder structure 186 (which may be substituted by another electrically conductive connection structure) so that the oblong electric connection element 154 extends for conducting electricity from the clip 110 along the mounting base 152. Hence, the oblong electric connection element 154 extends horizontally according to FIG. 1 and FIG. 2 and parallel to a horizontal plane of the plate-shaped mounting base 152. In particular, the oblong electric connection element 154 is electrically connected directly horizontally on the clip 110. As shown, the encapsulant 106 only partially encapsulates the clip 110 and only partially encapsulates the carrier 102. In contrast to this, the encapsulant 106 fully encapsulates the electronic components 104. As a result, the electronic components 104 are mechanically and electrically protected against impact from the environment. The carrier 102 is exposed for establishing an electric connection with the mounting base 152 and for bottom-sided cooling. The clip 110 is exposed for establishing the electric connection with the oblong electric connection element 154 and for top-sided cooling.

By the exposure of the upper main surface of the clip 110 beyond the encapsulant 106 and the direct horizontal connection with the oblong electric connection element 154, an excellent thermal reliability may be achieved. As a result, the electronic device 150 may be operated with a higher power and/or the cooling effort may be reduced (for instance by optionally omitting a heat sink).

Any of the electrically conductive connection structures described above referring to reference signs 180, 182, 184, 186 can be for example a solder connection, a sinter connection, and/or an electrically conductive glue connection. Alternatively, the electrically conductive connection structures described above referring to reference signs 180, 182, 184, 186 may also be omitted when the respective electrically conductive members are connected with each other by a direct metal-to-metal bonding technology, for instance by hybrid bonding.

FIG. 3 illustrates a plan view of an electronic device 150 according to an exemplary embodiment.

According to FIG. 3, three packages 100 may be mounted on mounting base 152, which may be a PCB. Each of the packages 100 may be constructed for example as described above referring to FIG. 1 and FIG. 2. From each of the packages 100, a respective oblong electric connection element 154, which is here embodied as a cable 156, extends directly from a solder connection with the exposed clip 110 along the mounting base 152 (for instance horizontally). The three oblong electric connection elements 154 may be connected with an electric motor 162. The three half-bridges provided by the three packages 100 may correspond to three phases of a three-phase electric motor 162. Thus, the electric connections U1, V1, W1 shown in FIG. 3 relate to three phase node connections. Each of the three packages 100 is connected with two direct current power supply terminals 188, 190 on mounting base 152 which may be connected to a positive pole (“+”) and a negative pole (“−”), respectively, of a direct current (DC) power supply, such as a battery (not shown), for powering the electric motor 162. Moreover, one or more passive components 198 (for instance capacitors) may be surface mounted on mounting base 152 as well.

Hence, FIG. 3 shows a PCB-type mounting base 152 with scalable half bridge-type packages 100 having exposed clips 110 being directly soldered with cable-type oblong electric connection elements 154. Thus, half bridges with solderable exposed phase node pad and direct soldered cable may be provided.

FIG. 4 illustrates a plan view of an electronic device 150 according to another exemplary embodiment.

The embodiment of FIG. 4 differs from the embodiment of FIG. 3 in particular in that, according to FIG. 4, the oblong electric connection elements 154 are embodied as strip-shaped metal sheets 158 being coupled with bulk connectors 160. In addition, a respective cable 156 is provided which is electrically connected with the assigned metal sheet 158. This coupling can be accomplished by a respective electrically conductive bulk connector 160 being surface mounted on the mounting base 152 for vertically protruding therefrom. Each respective bulk connector 160 electrically connects the respective cable 156 with the assigned metal sheet 158. For example, this may be achieved by screwing a screw (not shown) into a recess, with internal thread, of the respective electrically conductive bulk connector 160. Each bulk connector 160 may have a height which is significantly larger than a height of the respective package 100. Preferably, each bulk connector 160 may be embodied as a massive cylindrical metal block provided apart from the packages 100.

To put it shortly, the embodiment of FIG. 4 provides a PCB-type mounting base 152 with scalable half bridge-type packages 100 having exposed clips 110 being directly soldered with copper sheet-type oblong electric connection elements 154 which may be screwed to bulk connector 160. Thus, half bridges with solderable exposed phase node pad and direct soldered metal sheets 158 may be provided. The latter may be attached via SMD (surface mounted device)-type bulk connectors 160 to the respective phase node cable 156. This may reduce mechanical stress applied to the electronic device 150 and its constituents. In particular, undesired tear off of cables 156 may be reliably prevented which renders electronic device 150 more robust.

FIG. 5 illustrates a plan view of an electronic device 150 according to another exemplary embodiment.

The embodiment of FIG. 5 differs from the embodiment of FIG. 3 in particular in that, according to FIG. 5, the oblong electric connection elements 154 are embodied as strip-shaped metal sheets 158. Cables 156 may be soldered directly onto the metal sheets 158.

Hence, FIG. 5 shows a PCB-type mounting base 152 with scalable half bridge-type packages 100 having exposed clips 110 being directly soldered with metal sheet-type oblong electric connection elements 154. Thus, half bridges with solderable exposed phase node pad and direct soldered metal sheets 158 may be provided. The latter may be directly connected to the respective phase node cable. This may be done without the need of SMD (surface mounted device)-type bulk connectors, which renders electronic device 150 more compact.

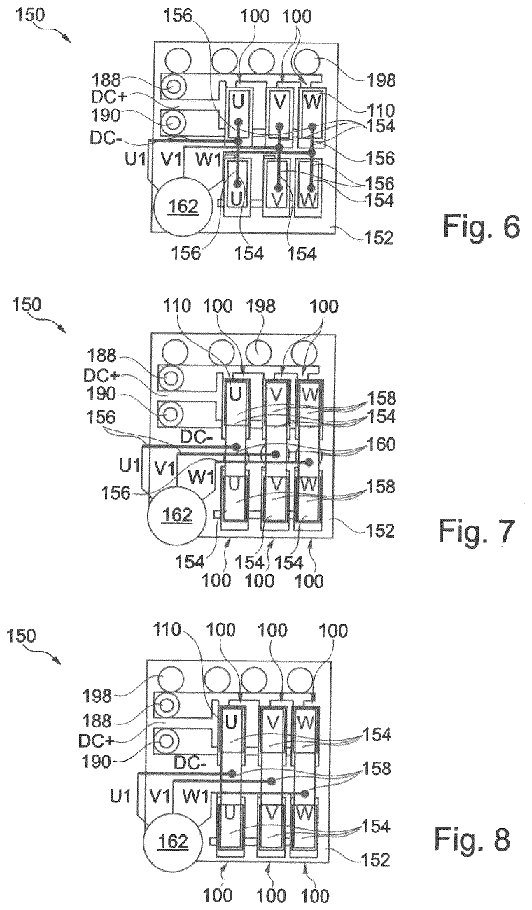

FIG. 6 illustrates a plan view of an electronic device 150 according to another exemplary embodiment.

The embodiment of FIG. 6 differs from the embodiment of FIG. 3 in particular in that, according to FIG. 6, six rather than three packages 100 of the type described referring to FIG. 3 are surface mounted on mounting base 152. Each of electric connections U1, V1, W1 is coupled with two packages 100. Thus, the embodiment of FIG. 6 serves for paralleling of half bridges.

FIG. 7 illustrates a plan view of an electronic device 150 according to another exemplary embodiment.

The embodiment of FIG. 7 differs from the embodiment of FIG. 4 in particular in that, according to FIG. 7, six rather than three packages 100 of the type described referring to FIG. 4 are surface mounted on mounting base 152. Each of electric connections U1, V1, W1 is coupled with two packages 100. Thus, the embodiment of FIG. 7 serves for paralleling of half bridges. Each half bridge is provided with a solderable exposed phase node pad and a soldered copper sheet 158 which is attached via a respective SMD connector 160 to an assigned phase node cable 156, which may be a direct soldered cable. This embodiment may help to reduce mechanical stress.

FIG. 8 illustrates a plan view of an electronic device 150 according to another exemplary embodiment.

The embodiment of FIG. 8 differs from the embodiment of FIG. 5 in particular in that, according to FIG. 8, six rather than three packages 100 of the type described referring to FIG. 5 are surface mounted on mounting base 152. Each of electric connections U1, V1, W1 is coupled with two packages 100. Thus, the embodiment of FIG. 8 serves for paralleling of half bridges.

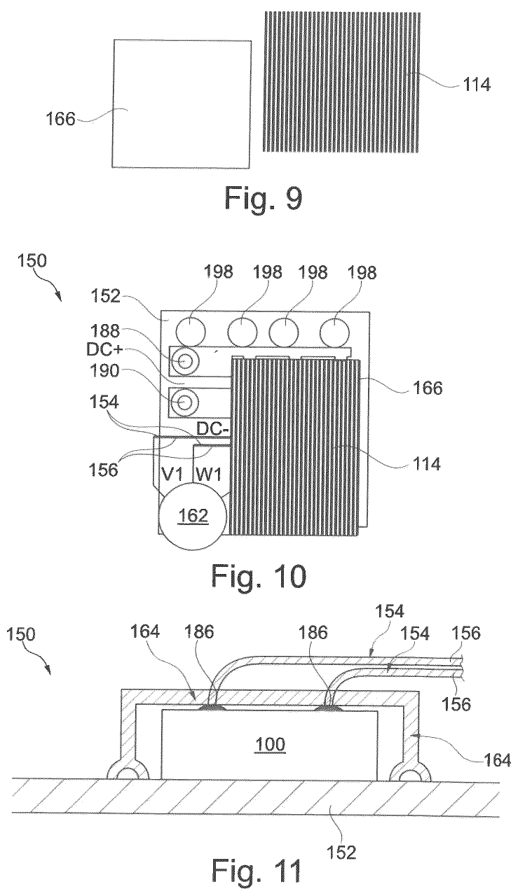

FIG. 9 illustrates a plan view of a cooling structure 114 and a thermal interface material 166 of an electronic device 150 according to an exemplary embodiment. FIG. 10 illustrates a plan view of an electronic device 150 with such a cooling structure 114 and such a thermal interface material 166 according to an exemplary embodiment.

The cooling structure 114, shown in isolation in FIG. 9, may be constructed for example with a plate-shaped base body with a plurality of cooling fins extending therefrom. The electrically insulating thermal interface material (TIM) 166, shown in isolation in FIG. 9, may be provided between the cooling structure 114 and the respective package 100 for providing dielectric protection and thermal coupling.

Now referring to FIG. 10, the thermal interface material 166 may be provided directly on the oblong electric connection elements 154 and on the exposed clips 110. The cooling structure 114 may then be attached on the thermal interface material 166 for providing a thermal coupling path from the oblong electric connection elements 154 and the clips 110 through the thermal interface material 166 up to the cooling structure 114. This ensures an excellent thermal performance of the electronic device 150. Together with the exposed main surfaces of the carrier 102, the cooling structure 114 may provide a heat sink for highly efficient double side cooling.

The configuration with cooling structure 114 and thermal interface material 166 can be provided for any of the embodiments of FIG. 1 to FIG. 8, and also to the embodiments of FIG. 10 and FIG. 11 (where cooling structure 114 and thermal interface material 166 can be provided on top of protection structure 164).

In an alternative embodiment, in which compactness is a priority, cooling structure 114 and thermal interface material 166 may also be omitted.

FIG. 11 illustrates a cross-sectional view of an electronic device 150 with protection structure 164 according to another exemplary embodiment.

FIG. 11 shows a package 100 with oblong electric connection elements 154 which may be embodied as directly solder-connected cables 156 (or alternatively as metal strips, not shown in FIG. 11). In particular when cables 156 are used, there may be a risk that the cables 156 tear off from the package 100 when the electronic device 150 is operated under harsh conditions. In order to improve the mechanical integrity of the electronic device 150, a protection structure 164 may be provided for clamping the package 100 and the oblong electric connection elements 154 together. This may protect the oblong electric connection elements 154 from tearing off. For example, the mechanical protection structure 164 may be embodied as a busbar, for instance made of copper. More generally, protection structure 164 may be made of a metal or a ceramic. In one embodiment, the protection structure 154 may be fixed at the mounting base 152, although this is optional.

The embodiment of FIG. 11 provides a half bridge-based electronic device 150 with solderable exposed phase node pads and an external protection clip for protecting a direct soldered cable 156 for increasing mechanical stability.

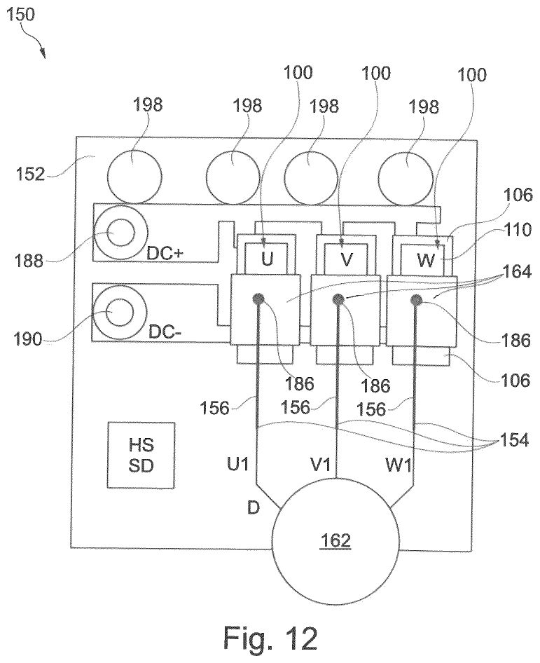

FIG. 12 illustrates a plan view of an electronic device 150 with protection structures 164 according to another exemplary embodiment. The embodiment of FIG. 12 corresponds to the embodiment of FIG. 3, however protects the cables 156 being directly connected to the clips 110 by a solder structure 186 with protection structures 164, which may be embodied for example as described referring to FIG. 11.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An electronic device, comprising:
a mounting base;
an oblong electric connection element; and
a package mounted on the mounting base and comprising:
a carrier;
electronic components mounted on the carrier;
an encapsulant at least partially encapsulating the carrier and the electronic components; and
a clip connected to upper main surfaces of the electronic components;
wherein the encapsulant partially encapsulates the clip so that an exposed surface of the clip is directly electrically connected with the oblong electric connection element so as to extend for conducting electricity from or to the clip along at least part of the mounting base;
wherein the oblong electric connection element is electrically connected directly horizontally on exposed surface of the clip.

2. The electronic device according to claim 1, wherein the oblong electric connection element is electrically connected on the clip by one of the group comprising a solder connection, a sinter connection, and a glue connection.

3. The electronic device according to claim 1, wherein the oblong electric connection element comprises or consists of a cable.

4. The electronic device according to claim 1, wherein the oblong electric connection element comprises a metal sheet, for example a metal strip.

5. The electronic device according to claim 4, comprising a cable being electrically connected with the metal sheet.

6. The electronic device according to claim 5, comprising an electrically conductive bulk connector electrically connecting the cable with the metal sheet, for example by screwing.

7. The electronic device according to claim 6, wherein the electrically conductive bulk connector is mounted on and extends vertically from the mounting base.

8. The electronic device according to claim 6, wherein the electrically conductive bulk connector is a metal block, in particular a cylindrical metal block.

9. The electronic device according to claim 5, wherein the cable is directly electrically connected with the metal sheet, for example by screwing.

10. The electronic device according to claim 1, comprising:
at least one further package according to claim 1, mounted on the mounting base; and
at least one further oblong electric connection element being electrically connected directly on top of at least one further clip of the at least one further package so as to extend for conducting electricity from or to the at least one further clip along at least part of the mounting base.

11. The electronic device according to claim 1, comprising an electric motor electrically coupled with the package, with the oblong electric connection element.

12. The electronic device according to claim 1, comprising a cooling structure, having a base body with a plurality of cooling fins extending therefrom, arranged directly on the oblong electric connection element and/or on the clip.

13. The electronic device according to claim 12, comprising an electrically insulating thermal interface material between, on the one hand, the cooling structure and, on the other hand, the oblong electric connection element and/or the clip.

14. The electronic device according to claim 1, comprising a protection structure clamping the package and the oblong electric connection element together for protecting the oblong electric connection element from tearing off.

15. The electronic device according to claim 1, comprising at least one of the following features:
wherein the electronic components are semiconductor dies;
wherein each of the electronic components comprises an integrated transistor;
wherein the electronic components are configured and connected to provide a half-bridge function;
wherein the clip is connected to an upper main surface of the carrier.

16. A method of manufacturing an electronic device, the method comprising:
forming a package by
mounting electronic components on a carrier;
at least partially encapsulating the carrier and the electronic components by an encapsulant; and
connecting a clip to upper main surfaces of the electronic components;
mounting the package on a mounting base;
encapsulating partially the clip so that the top surface of the clip exposed; and
electrically connecting an oblong electric connection element directly on top surface of the clip so as to extend for conducting electricity from or to the clip along at least part of the mounting base so as to extend directly horizontally from the clip.

17. The method according to claim 18, wherein the method comprises electrically connecting the oblong electric connection element on the clip by one of the group comprising soldering, sintering, and gluing.
